(19) United States
(12) Patent Application Publication
(10) Pub. No.: US 2002/0072225 A1
(43) Pub. Date: Jun. 13, 2002

(54) Hard-mask etch process

(76) Inventors: Reima T. Laaksonen, Dallas, TX (US); Freidoon Mehrad, Plano, TX (US); Cameron S. Gross, Allen, TX (US)

Correspondence Address: TEXAS INSTRUMENTS INCORPORATED, P O BOX 655474, M/S 3999, DALLAS, TX, 75265

(21) Appl. No.: 09/967,165

(22) Filed: Sep. 28, 2001

Related U.S. Application Data
(60) Provisional application No. 60/243,071, filed on Oct. 25, 2000.

(51) Int. Cl. H01L 21/4763

(52) U.S. Cl. 438/636

(57) ABSTRACT

A method is described for forming a patterned polysilicon, amorphous, or single crystal silicon layer. The method comprises forming a consumable mask (50, 60) that is simultaneously removed while etching the underlying film (30).

### FIELD OF THE INVENTION

The present invention relates to a method of forming a polysilicon gate structure using a hardmask polysilicon etch process.

### BACKGROUND OF THE INVENTION

A good control of the critical dimension (CD) is crucial for the performance of microelectronic devices.

As CMOS technology pushes deeper into the submicron region, the control of critical dimensions of the devices becomes more difficult. A commonly used method to achieve better CD control is to use a bottom antireflective coating (BARC) below the photoresist. Both organic and inorganic BARC materials are used. The advantages of organic BARC are that it is easy to remove. However, the inorganic BARC has better anti-reflective properties than organic BARC. This leads to better CD control. The disadvantage of inorganic BARC is the difficulty in removing this BARC from the semiconductor wafer. Use of inorganic BARC requires elaborate clean-up and/or process integration schemes. This often leads to an increase in defect levels and the corresponding deterioration in device performance. There is therefore a need for an improved BARC process.

### SUMMARY OF INVENTION

The instant invention describes an improved hark mask method for forming a patterned layer. The method comprises forming a consumable hark mask that is simultaneously removed while etching the underlying film. In particular the instant invention comprises forming a film to be patterned on a semiconductor wafer. An ARC film, an optically transparent film, and a photoresist film is formed over this film. Using a number of processing steps including photolithography and film etching a pattern is formed in the film. The instant invention offers that advantage of using an inorganic reflective film without the accompanying film removal and clean-up problems.

### BRIEF DESCRIPTION OF THE DRAWINGS

For a more complete understanding of the present invention and the advantages thereof, reference is now made to the following description taken in conjunction with the accompanying drawings, wherein like reference numerals represent like features, in which:

FIGS. 1-3 are cross-section diagrams showing the formation of a polysilicon line using the method of the instant invention.

### DETAILED DESCRIPTION OF THE INVENTION

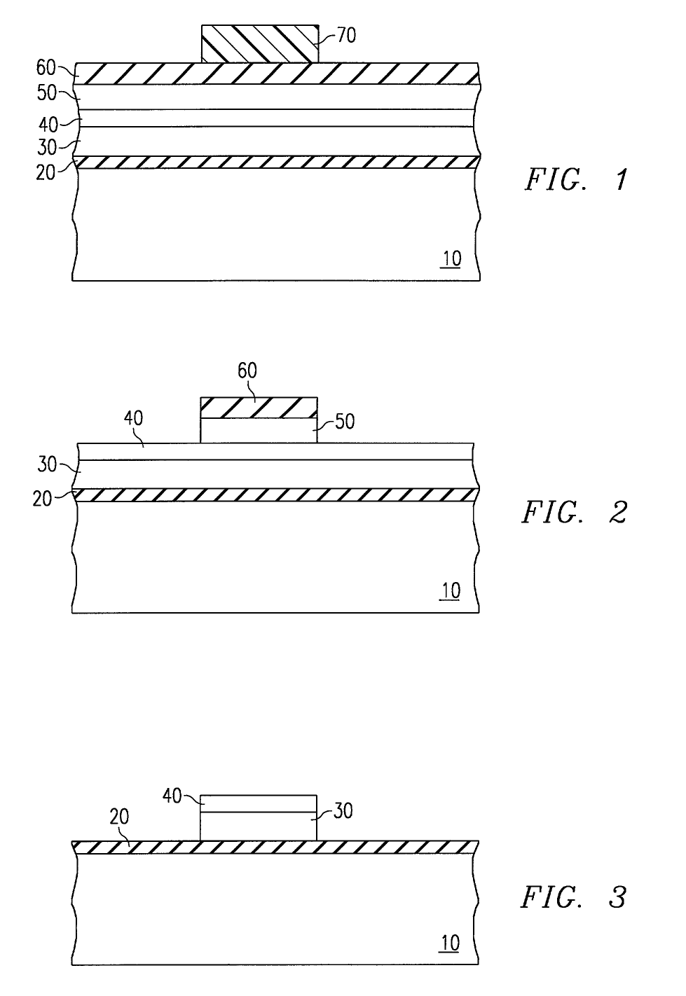

Illustrated in FIGS. 1-3 are cross-section diagrams showing the formation of a polysilicon line using the method of the instant invention. Polysilicon lines formed using the instant invention will be used to form MOS transistor gates, resistors, MOS capacitor gates, and a variety of other integrated circuit device components. The invention will be described with reference to forming the gate of a MOS transistor. It is not intended however that the method of the instant invention be limited to this device. Many additional applications of the instant invention will be apparent to those of ordinary skill in the art.

Referring to FIG. 1, a semiconductor body 10 is provided. If a polysilicon MOS transistor gate is to be formed, a transistor dielectric layer 20 is formed on the surface on the semiconductor body. As discussed earlier, the invention is not limited to polysilicon MOS transistor gates and may be used for polysilicon lines in general. Following the formation of the gate dielectric layer 20, a polysilicon layer 30 is formed on the gate dielectric layer 20. A silicon oxide polysilicon capping layer 40 is then formed on the surface of the polysilicon layer 30. This silicon oxide capping layer can be formed by the thermal oxidation of the surface of the polysilicon layer 30 or deposited using a chemical vapor deposition (CVD) process. In addition to silicon oxide, silicon oxynitride, and silicon nitride can also be used to form the polysilicon capping layer 40. For typical thickness values (i.e. 800A-2500A) of the polysilicon film 30, the thickness of the silicon oxide capping layer 40 should be about 25A-130A. Following the formation on the polysilicon capping layer 40, a layer of anti-reflective coating (ARC) 50 is formed. In an embodiment of the instant invention, this ARC layer 50 is comprised of silicon oxynitride. In addition to silicon oxynitride, silicon nitride, as well as any other suitable inorganic ARC layer can be used. The thickness of the ARC layer 50 should be chosen such that the amount of light reflected in minimized during subsequent photoresist patterning. The thickness of the ARC layer 50 will therefore depend on the frequency of light used. For the wavelengths currently used for photoresist development, silicon oxynitride ARC layer thickness of 100A to 400A can be used to form layer 50. Following the formation of the ARC layer 50, an optically transparent dielectric (OTD) layer or film 60 is formed on the ARC layer. Ideally this OTD layer or film 60 should have no optical absorption for the wavelength of light used for the subsequent photoresist development. For purposes of the instant invention, an optically transparent film can be defined as a film that absorbs less than 70% of the light that traverses the film. In an embodiment of the instant invention, a chemical oxide film such as a SILOX film can be used to form the OTD layer 60. SILOX is a chemical silicon oxide film formed using CVD process and is mostly transparent to light. For the wavelengths currently used for photoresist development, a SILOX film thickness of 25A to 300A can be used to form the OTD layer 60. The OTD layer 60 and the ARC layer 50 will form the hard-mask structure of the instant invention. In general, the hard-mask of the instant invention is formed by a multi-layer structure comprising an ARC dielectric layer and a OTD layer. Following the formation of the OTD layer 60, a photoresist layer is formed on the OTD layer 60. This photoresist film, which can comprise standard photoresist such as UV 110 or UV 5, is patterned using standard methods of exposure and development. A patterned photoresist layer 70 is shown in FIG. 1.

Following the formation of the hard-mask structure shown in FIG. 1, the various layers which comprise the hard-mask will be etched before etching the polysilicon layer 30. Referring to FIG. 2, The hard-mask structure which is not covered by the photoresist 70 is etched in a DPS chamber using a multi-step etch process.

Firstly the CD of the resist is reduced using a CD trim etch. This is a RIE/plasma based etch process based on the following recipe:

| Parameter (Units) | |
|---|---|
| Time (secs) | 5-40 |
| Pressure (mtorr) | 3-12 |
| Bias (Watts) | 50-125 |
| Source (Watts) | 280-350 |
| HBr (sccm) | 50-125 |
| O₂ (sccm) | 20-85 |

This CD trimming process is followed by a hard-mask etch process that will remove the OTD layer 60 and the ARC layer 50. In an embodiment of the instant invention the following plasma based process can be used:

| Parameter (Units) | |
|---|---|
| Time (secs) | end-point |
| Pressure (mtorr) | 2-7 |
| Bias (Watts) | 25-80 |
| Source (Watts) | 350-700 |
| O₂ (sccm) | 2-10 |
| CF₄ (sccm) | 30-80 |

The above hard-mask removal process will remove the OTD layer 60, the ARC layer 50, and end-point (or stop) on the polysilicon capping layer 40. Following removal of the hard-mask, the remaining photoresist 70 is removed using as plasma-based ash process. The photoresist can be removed in the same tool or equipment chamber that was used to perform the previous etch step. In an embodiment of the instant invention the following ash process can be use to remove the photoresist film 70:

| Parameter (Units) | |
|---|---|
| Time (secs) | End-point |
| Pressure (mtorr) | 75-130 |
| Bias (Watts) | 175-130 |
| Source (Watts) | 800-1300 |
| O₂ (sccm) | 80-150 |
| N₂ (sccm) | 100-350 |

The remaining structure is shown in FIG. 2. The remaining ARC layer 50 and remaining OTD layer 60 will serve as the hard-mask during the subsequent polysilicon etch process.

The polysilicon layer and the remaining hard-mask (i.e. 50 and 60) will be simultaneously etched using a further multi-step etch process. Thus during the plasma based etching processes that are used to etch the polysilicon layer 30, the ARC layer 50 and the OTD layer 60 will also be etched.

The first step in this multi-step etch process is a break-through (BT) etch step used to clear the top of the polysilicon layer 30. This BT etch step is to assure that all dielectric material is removed over regions not covered by the hard-mask. In addition, a portion of the OTD layer will be removed during this BT etch step. In an embodiment of the instant invention, the plasma based BT etch process will comprise the following process:

| Parameter (Units) | |
|---|---|
| Time (secs) | 3-25 |
| Pressure (mtorr) | 2-10 |
| Bias (Watts) | 20-70 |
| Source (Watts) | 200-900 |
| CF₄ (sccm) | 20-70 |

Following the removal of the polysilicon capping layer 40, the polysilicon layer 30 and the remaining hard-mask is etched using the remaining steps of the multi-step etch process.

The second step of this multi-step etch process is the main polysilicon etch. This etch step will remove the majority of the polysilicon layer 30 and the remaining TD layer 60. In an embodiment of the instant invention, the plasma based main etch process comprises:

| Parameter (Units) | |
|---|---|
| Time (secs) | 10-30 |
| Pressure (mtorr) | 2-25 |
| Bias (Watts) | 75-130 |
| Source (Watts) | 600-1200 |
| CF₄ (sccm) | 10-40 |
| CL₂ (sccm) | 25-85 |
| HBr (sccm) | 40-150 |
| HeO₂ (sccm) | 5-35 |

Following the main etch process, the remaining unmasked polysilicon 30 and the remaining ARC layer 50 will be removed using the following polysilicon end-point etch process, and the polysilicon over-etch etch process. In an embodiment of the instant invention, the polysilicon end-point etch process will comprise:

| Parameter (Units) | |
|---|---|
| Time (secs) | End-point |
| Pressure (mtorr) | 10-60 |
| Bias (Watts) | 55-130 |
| Source (Watts) | 200-800 |
| Cl₂ (sccm) | 8-40 |
| HBr (sccm) | 120-220 |
| HeO₂ (sccm) | 10-50 |

and the polysilicon over-etch process will comprise:

| Parameter (Units) | |
|---|---|
| Time (secs) | 20-90 |
| Pressure (mtorr) | 75-130 |
| Bias (Watts) | 95-190 |
| Source (Watts) | 800-1300 |
| HBr (sccm) | 110-250 |
| HeO₂ (sccm) | 5-50 |

The polysilicon over-etch process is very selective to the polysilicon capping layer 40 and this layer will remain over the etched polysilicon line. This capping layer protects the polysilicon line from being etched vertically. The completed etch polysilicon line 35 and the remaining capping layer 45 is shown in FIG. 3.

In the embodiment described above, the polysilicon structure 30 will form the gate of a MOS transistor. The MOS transistor can be completed using standard silicon processing. It should be recognized however that such an etched polysilicon structure could be used in any number of polysilicon devices. In addition, the invention was described with reference to polysilicon silicon. Other silicon material such as amorphous silicon or single crystal silicon could be used in place of polysilicon without changing the scope of the invention. Thus the multi-layer hard-mask and simultaneous etch process does not depend on the structure or type of the film to be etched.

While this invention has been described with reference to illustrative embodiments, this description is not intended to be construed in a limiting sense. Various modifications and combinations of the illustrative embodiments, as well as other embodiments of the invention will be apparent to persons skilled in the art upon reference to the description. It is therefore intended that the appended claims encompass any such modifications or embodiments.

We claim:

1. A method for forming an etched line comprising:
providing a semiconductor substrate;
forming a first film over said substrate;
forming a patterned ARC film over said first film wherein said patterned ARC film is formed in a first pattern;
forming a patterned optically transparent film over said ARC film wherein said patterned optically transparent film is also formed in said first pattern; and
transferring said first pattern to said first film by simultaneously etching said first film, said patterned ARC film, and said patterned optically transparent film.

2. The method of claim 1 wherein said forming a patterned optically transparent film and forming a patterned ARC film, comprises:
forming a blanket ARC film;
forming a blanket optically transparent film;
forming a photoresist film on said optically transparent film;
patterning said photoresist film thereby exposing certain regions of said optically transparent film;
etching said exposed regions of said optically transparent film;
etching that portion of the ARC film that lay beneath the exposed regions of said optically transparent film; and
removing said photoresist film.

3. The method of claim 1 further comprising forming a capping layer between said first film and said ARC film.

4. The method of claim 1 wherein said first film comprises a material selected from the group consisting of polysilicon, single crystal silicon, and amorphous silicon.

5. The method of claim 1 wherein said patterned ARC film comprises silicon oxynitride.

6. The method of claim 1 wherein said optically transparent film comprises a chemical silicon oxide.

7. the method of claim 1 wherein said transferring said first pattern to said first film by simultaneously etching said first film, said patterned ARC film, and said patterned optically transparent film comprises etching with a plasma based etch process.

8. A consumable inorganic hard-mask for polysilicon etching, comprising:
an inorganic ARC layer with an upper surface; and
an optically transparent layer formed on said upper surface of said ARC layer.

9. The consumable inorganic hard-mask of claim 8 wherein said inorganic ARC layer is silicon oxynitride.

10. The consumable inorganic hard-mask of claim 9 wherein said optically transparent layer is a chemical silicon oxide.

11. A method for forming an etched line comprising:
providing a semiconductor substrate;
forming a polysilicon layer over said substrate;
forming a capping layer on said polysilicon layer;
forming an ARC film on said capping layer;
forming an optically transparent film on said ARC;
forming a photoresist film on said optically transparent film;
patterning said photoresist film thereby exposing certain regions of said optically transparent film;
etching said exposed regions of said optically transparent film;
etching that portion of the ARC film that lay beneath the exposed regions of said optically transparent film;
removing said photoresist film; and
etching simultaneously said first film, said ARC film, and said optically transparent film to pattern said polysilicon layer and simultaneous remove said optically transparent film and said ARC film.

12. The method of claim 11 wherein said ARC film comprises silicon oxynitride.

13. The method of claim 12 wherein said optically transparent film comprises a chemical silicon oxide.

14. the method of claim 11 wherein said etching simultaneously comprises etching with a plasma based etch process.
